(19) United States
(12) Patent Application Publication
(10) Pub. No.: US 2015/0245532 A1
(43) Pub. Date: Aug. 27, 2015

(54) SELF MODULATING AIR REGISTER TECHNOLOGY (SMART) FLOOR TILE FOR DATA CENTERS AND OTHER APPLICATIONS

(71) Applicants: ACTA TECHNOLOGY INC., Boulder, CO (US); ACTA TECHNOLOGY INC., Boulder, CO (US); ACTA TECHNOLOGY INC., Boulder, CO (US); ACTA TECHNOLOGY INC., Boulder, CO (US)

(72) Inventors: Edward Vincent Clancy, Boulder, CO (US); Albert Dean Jefferson, Fairfield, CA (US); JOHN MELVIN OLSON, Boulder, CO (US); ROGER THOMAS DIRSTINE, Loveland, CO (US)

(73) Assignee: ACTA TECHNOLOGY INC., Boulder, CO (US)

(21) Appl. No.: 14/187,370

(22) Filed: Feb. 24, 2014

(51) Int. Cl. H05K 7/20

(52) U.S. Cl. CPC H05K 7/20009

(57) ABSTRACT

This invention is a novel air supply register that modulates the incoming air supply from the under floor air duct. This air register is able to monitor the air temperature leaving the server stack thereby improving the response time of the HVAC system. Since the register has adjustable louvers that can modulate the inlet air flow into the server stack; it will save energy by reducing the supply air to the server stack when the cool incoming air is not needed. This reduces hot spots in the data center because the cool incoming air can be directed to server racks that need cooling. This self-modulation of the air register is not available in conventional floor registers.

### REFERENCE TO RELATED APPLICATIONS

Earlier Provisional Patent No. 61/769,569 DATED 26 Feb. 2013.

### STATEMENT REGARDING FEDERALLY SPONSORED RESEARCH OR DEVELOPMENT

The research was partially funded by the U.S. National Science Foundation. The grant award number is 0944681.

### BACKGROUND OF THE INVENTION

Information Technology sector's (IT) data centers use significant amount of energy and therefore provide an excellent opportunity for using a self-modulating air register technology (SMART) in place of conventional floor registers in order to save energy. The EPA (Environmental Protection Agency) and the DOE (Department of Energy) estimate the IT sector of the economy consumed 61 billion kilowatt-hours (kWh) in 2006. This is 1.5 percent of total U.S. electricity consumption for a total electricity cost of about $4.5 billion. The IT sector's energy consumption doubled from 2000 to 2006 and was expected to double again by 2011. Therefore having energy efficient Data Centers is a national priority. The IT sector is looking for energy efficient improvement solutions such as SMART.

The power and cooling infrastructure that supports IT equipment in data centers accounts for fifty (50) percent of the total energy consumption of data centers. This invention improves the Heating Ventilation and Air Conditioning (HVAC) system for these data centers.

Computer servers are located in data centers and are typically on-line 24 hours a day, 7 days a week, handling e-mails, processing internet requests, safeguarding classified data, handling financial transactions, and storing video and medical records. The continued increase use of the internet will only increase as more and more applications are developed and expanded.

Computer server's temperatures are not uniform. In fact high speed circuit such as fixed point and floating pointing point units in CPUs, phased lock loops/clock generators, and multiple function in the graphics/video/3D capabilities cause hot spots while the cache region on the chips are the coolest. Therefore the temperature is not uniform in a typical data center. The HVAC air supply system should be able to better manage these hot spots.

This invention is a novel air supply register that modulates the incoming air supply from the under floor air duct. This air register is able to monitor the air temperature leaving the server stack thereby improving the response time of the HVAC system. Since the register has adjustable louvers that can modulate the inlet air flow into the server stack; it will save energy by reducing the supply air to the server stack when the cool incoming air is not needed. This reduces hot spots in the data center because the cool incoming air can be directed to server racks that need cooling. This self-modulation of the air register is not available in conventional floor registers.

In the preferred embodiment, the air register uses gear driven louvers that saves energy because the gears are able to modulate the incoming air supply. Linkage can also be used instead of gears. The type of gears include spur, herringbone, rack, worm, bevel/miter, and helical gears. The modulating air register operates as a Variable Air Volume (VAV) system. For example, the modulated louver can reduce the volume of air from 100% supply to 80% supply if the exiting temperature is lower than set point and this will result in approximately a 50% savings in fan energy. The inlet (cold) supply air can then be re-directed to parts of the data center that needs cool supply air. One skilled in the art knows that higher operating temperatures reduce the reliability of computer servers and other electronic equipment. These louvers therefore can improve the reliability of the server and prevent hot spots within the data center and at the same time save energy. The size of the louver is the same as the dimensions of conventional floor registers that cannot automatically modulate the incoming air flow.

In the preferred embodiment, the louvers are moved by an actuator (Power Head) that requires no electricity motor or air actuator to move the air register's louvers. The system uses phase change material to power the air register's louvers. The phase change material can be a wax or a gas like Freon. A liquid with a high coefficient of expansion can also be used. In the preferred embodiment Freon 410A is used. The register is divided into 12 air cells in the preferred embodiment. Each cell has a louver in the cell. The cell provides structural strength to the floor register. There can be multiple cells depending on the size of register. For a two foot by two foot floor register has twelve (12) cells in the preferred embodiment. The register can be made from metal or plastic.

The focus of the patent is on data center's floor air registers; yet, the proposed technique can also be used as a low cost-effective method for improving ceiling air registers and other building HVAC systems registers where a VAV system is needed. The invention requires no power or air actuator to move the air register's louvers.

### BRIEF SUMMARY OF THE INVENTION

This invention uses the outlet air temperature from the computer server stacks (rack) to modulate the incoming air supply from the floor air register. A sensor (bulb) is placed in the outlet of the stack and monitors the outlet air temperature from the computer server's stack. This sensor uses phase change material to apply a force on a diaphragm, bellows, or piston in the power head. This force causes the louver linkage or gear to move which in turn causes the louvers to modulate the inlet air flow which is usually set for 55° F. incoming air. The outlet air temperature set point from the computer server stack is usually set for 78° F. This modulating air register improves the heat transfer of the computer server stacks. The invention also includes a novel way to operate the air register through a gear operated louvers. The invention includes a power head that includes a diaphragm, bellows, or piston that moves the air register louvers through a series of links. The power head and temperature bulb has a phase change material (PCM) in the bulb that creates a force to move the linkage of the air register. The result force causes the incoming air to be modulated. The air flow can be reduced when the exit temperature of the computer server stack is low (below the set point for the outlet of the rack e.g. below 78° F.) and the air flow can be increased when the exit temperature of the server stack is high (e.g. Above 78° F.).

The goal of the modulating air register is to produce a stable outlet temperature of the computer server stack. The set point for the outlet air temperature can be adjusted by adjusting the power head, chose of PCM material or the linkage that moves the louvers.

### BRIEF DESCRIPTION OF THE DRAWING

FIG. 1—Depicts a Data Center HVAC system using floor air registers.

FIG. 2—Depicts the Self Modulation Air Register with Power Head.

FIG. 3—Illustrates the gear driven air register louvers.

### DETAILED DESCRIPTION OF THE INVENTION

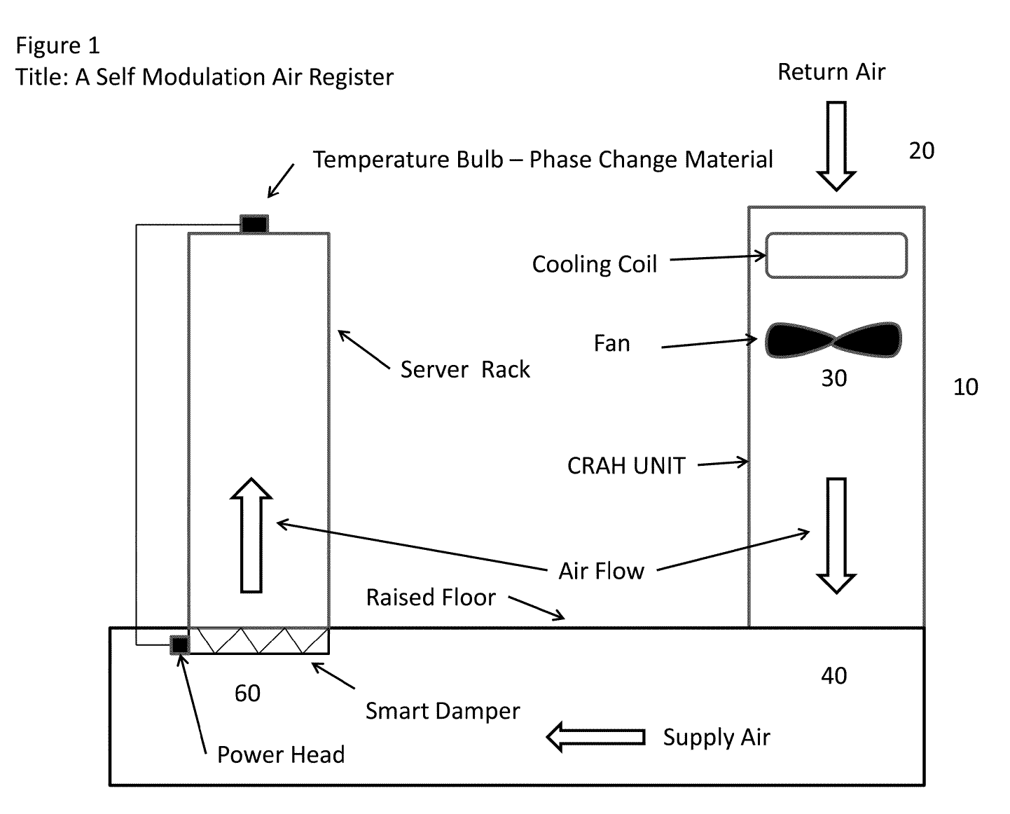

FIG. 1 illustrates a typical Data Center HVAC system that uses floor air registers. Air 20 enters the cooling coil 10 and is pumped into the floor cavity 40 by a fan 30. The air 20 is set to be 55° F. exiting the coiling coils 10. The cool inlet air flows to the modulating floor register 60. The floor register 60 receives a temperature signal 70 from the outlet of the computer server stack 80. The outlet temperature of the air leaving to computer server stack 80 is set for 78° F. If the exiting temperature is above the 78° F. set point the sensor 70 will send a signal to move the louvers of the air register 60 thereby increasing the amount of cooling air entering the computer server stack 80. Likewise if the exiting temperature is below the 78° F. set point the sensor 70 will send a signal to move the louvers of the air register 60 thereby decreasing the amount of cooling air entering the computer server stack 80. The 78° F. and 55° F. set points are adjustable.

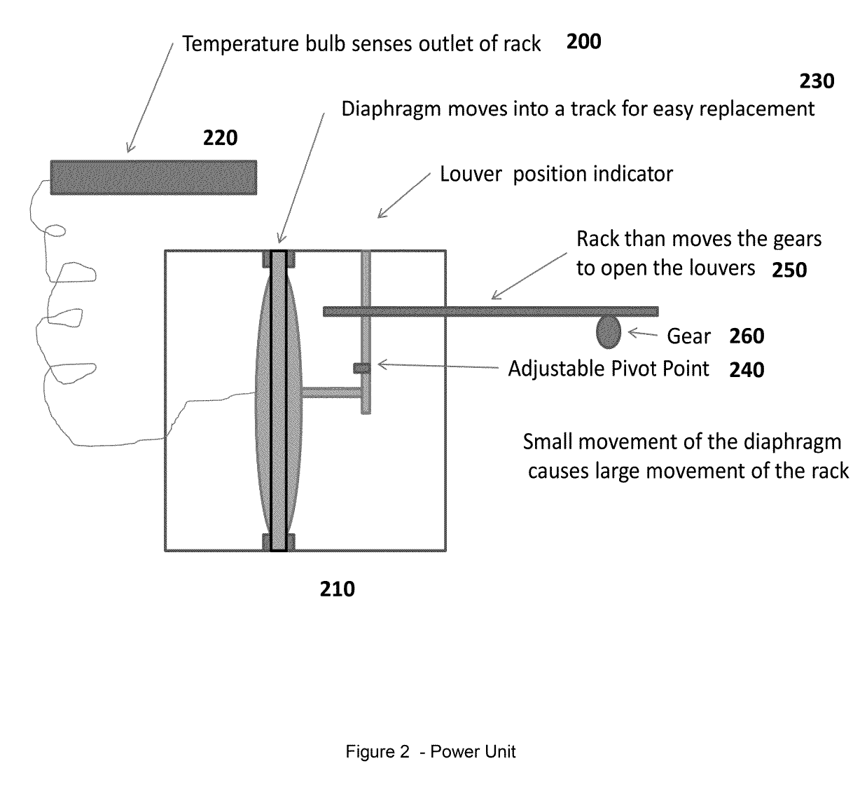

As depicted in FIG. 2, a sensor 200 is connected to a power unit 210. The sensor 200 has a phase change material 220 that sends a signal to the power unit 210. The signal is converted into force by either a diaphragm 230, bellows 230, or a piston 230. The movement of the diaphragm 230, bellows 230, or piston 230 moves linkage 240 which in turn spins a gear 260 or moves a second linkage 250 that opens or closes the air louvers. The temperature set point can be adjusted by moving the power head 210 or by moving (adjusting) the linkage 240.

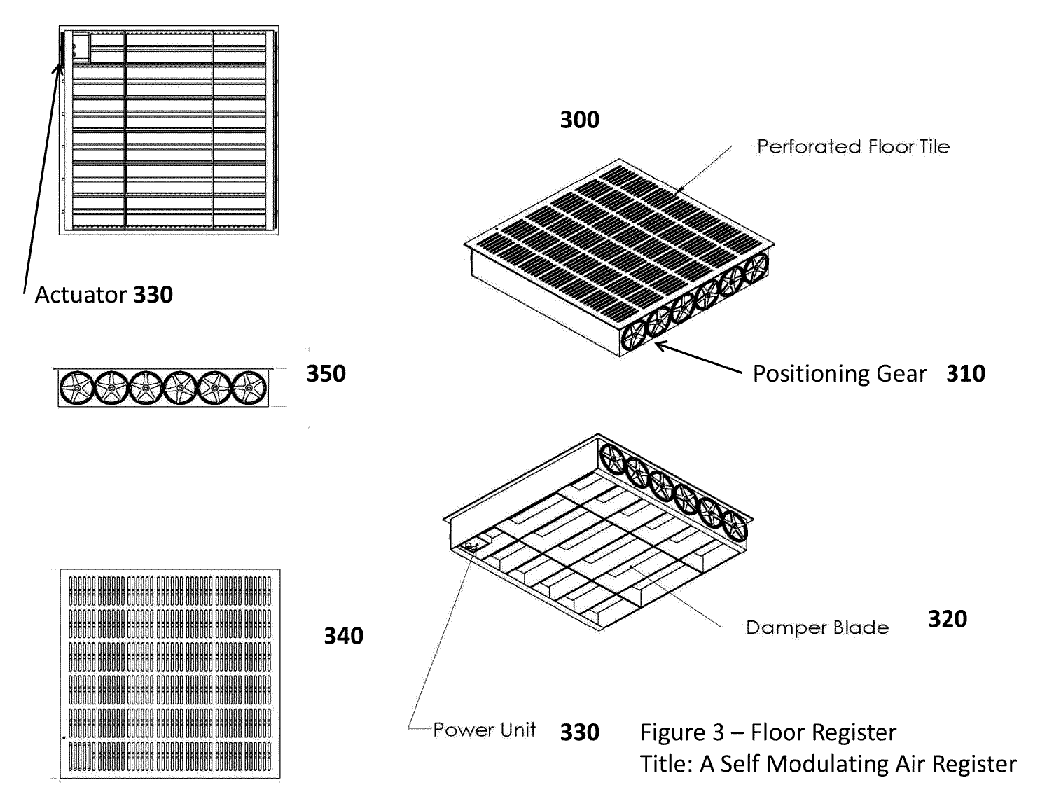

FIG. 3 depicts a gear operated air register 300. A plurality of gears 310 rotate the dampers or louvers 320. In the preferred embodiment the six gears 310 are used. An actuator 330 or power unit 330 moves the gears. The top of the register 300 is perforated 340 so that air can flow through the register. The gears 310 are modulated by the power unit 330 that receives a temperature signal from exiting temperature of the stack.

The phase change material (PCM) can be a wax, liquid or gas. Percent Freon is a PCM and is used in the preferred embodiment. Functionalized carbon nanotubes can also be used to the FREON to improve the kinetics of the device.

Carbon Nanotubes (CNT) with single wall and multi-walls can be used. In the preferred embodiment, the CNTs are treated with octadeclamine (ODA) surface treatment. Krytox™ 157 FSL or FSL can be used as a surfactant to hold the CNTs in suspension. Coated multi-wall or single wall carbon nanotubes can also be used that have a surface functionalized Mg—Al oxides coating. These functionalized CNTs have improved thermal conductivity. Krytox™, a DuPont product, is used as a dispersant for the CNTs. These coated or functionalized CNTs were easier to de-bundle as compared to uncoated CNTs.

Single wall or multiwall carbon nanotubes treated with octadecylamine (ODA) can be used with Krytox 157 FSL or Krytox 157 FSH and Freon to create a PCM. Krytox™ is a fluorinated surfactant which is perfluoropolyether carboxylic acid. This Freon nanofluid has a 93% improvement in thermal conductivity over the base Freon when 1.33% weight percent of functionalized CNTs are added to the Freon. The ration of Krytox to CNT is as low as 10:1 weight ration. Sonication power can be as low 30 Watts with sonication times as long as 60 minutes. The specific sonication conditions are governed by the sample size and the concentration of CNT.

Antifreeze (ethylene or propylene glycol) water mixtures can also be used. ACTA used fumed nanoparticles without a surfactant can also be used as a PCM.

The nanoparticles claimed are fumed alumina oxide (Al2O3), fumed titanium oxide (TiO2), fumed ferric oxide (Fe2O3), and fumed Aerosil™. Aerosil™ may contain 2% AL2O3 with 98% SiO2. One skilled in the art knows the fumed process. For example, fumed silica, also known as pyrogenic silica because it is produced in a flame.

The specification details embodiments of the invention. Other embodiments that are equivalent are also claimed.

What is claimed is:

1. An air register comprising of a base, frame, plurality of linkages, a plurality of power units to move a plurality of air louvers where the said air register is able to regulate the air exiting the said air register by monitoring the temperature of the exiting air from the said air register wherein the said power units uses a phase change material to move the said louvers through said linkages so that the outlet air of the said air register can be modulated.

2. The air register of claim 1, wherein the phase change material comprises a solid, or a liquid or a gas.

3. The air register of claim 1, wherein the louvers are modulated by a plurality of gears.

4. An air register of claim 1, wherein the phase change material comprises of Freon.

5. An air register of claim 1, wherein the power unit is a diaphragm, piston or bellows.

6. An air register comprising of a base, frame, plurality of linkages, a plurality of power units to move a plurality of air louvers where the said air register is able to regulate the air exiting the said air register by monitoring the temperature of the exiting air from the said air register wherein the said power units uses a phase change material to move the said louvers through said linkages so that the outlet air of the said air register can be modulate and the said phase material has carbon nanotubes in the said phase change material and a surfactant to hold the said carbon nanotubes in suspension.

7. An air register of claim 5, wherein the phase change material comprises of Freon with 0.00% to 10% single wall or multiwall carbon nanotubes treated with octadecylamine and perfluoropolyether carboxylic acid as a surfactant with a weight ratio of at least 10 parts surfactant to 1 part carbon nanotubes.

8. An air register of claim 5 wherein the phase change material comprises of Freon with 0.00% to 10% single wall or multiwall carbon nanotubes treated with functionalized Mg—Al oxides coating and perfluoropolyether carboxylic acid as a surfactant with a weight ratio of at least 10 parts surfactant to 1 part carbon nanotubes.

9. An air register comprising of a base, frame, plurality of linkages, a plurality of power units to move a plurality of air louvers where the said air register is able to regulate the air exiting the said air register by monitoring the temperature of the exiting air from the said air register wherein the said power units uses a phase change material to move the said louvers through said linkages so that the outlet air of the said air register can be modulated and the said phase change material is ethylene or propylene glycol water mixture with 0.0 to 99.9% water in the said mixture.

10. An air register of claim 8, wherein the phase change material comprises of propylene or ethylene glycol water mixture with 0.00% to 10% fumed nanoparticles and no surfactant to hold the fumed nanoparticles in suspension.

11. An air register in claim 8, wherein the fumed nanoparticles consist of the following: fumed alumina oxide (Al2O3), fumed titanium oxide (TiO2), fumed ferric oxide (Fe2O3), and fumed nanoparticles containing a mixture of 2% AL2O3 with 98% SiO2.
